(19) United States
(12) Patent Application Publication
(10) Pub. No.: US 2025/0040027 A1
(43) Pub. Date: Jan. 30, 2025

(54) SUBSTRATE WITH A CURRENT LIMITER

(71) Applicant: Micron Technology, Inc., Boise, ID (US)

(72) Inventors: Byung Hoon Moon, Taichung (TW); Seng Kim Ye, Singapore (SG)

(21) Appl. No.: 18/781,616

(22) Filed: Jul. 23, 2024

Related U.S. Application Data
(60) Provisional application No. 63/528,879, filed on Jul. 25, 2023.

(51) Int. Cl. H05K 1/02; H01L 23/00; H05K 1/18

(52) U.S. Cl. CPC H05K 1/0213; H05K 1/181; H01L 24/16; H01L 24/32; H01L 24/73; H01L 2224/16225; H01L 2224/32225; H01L 2224/73204; H05K 2201/10015; H05K 2201/10022; H05K 2201/10159

(57) ABSTRACT

A substrate is provided that includes a current limiter between Voltage Source (Vss) units on a Vss plane. The Vss plane includes a first Vss unit configured to provide a Vss signal to a first semiconductor device and a second Vss unit configured to provide a Vss signal to a second semiconductor device. The first and second Vss units include a first and second capacitor, respectively. The first and second capacitors are coupled through the current limiter, which can decrease the damage caused by electrostatic discharge events.

### CROSS-REFERENCE TO RELATED APPLICATION(S)

The present application claims priority to U.S. Provisional Patent Application No. 63/528,879, filed Jul. 25, 2023, the disclosure of which is incorporated herein by reference in its entirety.

### TECHNICAL FIELD

The present disclosure generally relates to semiconductor device assemblies and more particularly relates to a substrate with a current limiter.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic partial cross-sectional view of a substrate in accordance with an embodiment of the present technology.

FIG. 2 illustrates a simplified schematic partial plan view of a current limiter in accordance with an embodiment of the present technology.

FIG. 3 illustrates a simplified schematic partial plan view of a current limiter in accordance with an embodiment of the present technology.

FIG. 4 illustrates a simplified schematic partial plan view of a current limiter in accordance with an embodiment of the present technology.

FIG. 5 illustrates a simplified schematic cross-sectional view of a semiconductor device assembly in accordance with an embodiment of the present technology.

FIG. 6 illustrates a schematic view of a system that includes a semiconductor device assembly configured in accordance with an embodiment of the present technology.

FIG. 7 illustrates a method of fabricating a semiconductor device assembly in accordance with an embodiment of the present technology.

### DETAILED DESCRIPTION

A semiconductor device is assembled onto a package-level substrate to provide external connectivity to the device. Interconnects can be formed between the semiconductor device and the substrate to communicatively couple the semiconductor device and the substrate. The substrate can include connective structures (e.g., traces, lines, and vias) that extend between the semiconductor device and other circuit components. The connective structures can enable signaling between the substrate and the semiconductor device. For example, the substrate can include a Voltage Source (Vss) plane (e.g., a ground plane) and a positive voltage plane (e.g., Voltage Drain (Vdd) plane), and the various planes can carry power and ground signals to the semiconductor device.

During assembly, friction or residue at electric terminals connected with the Vss plane can cause charge to accumulate in capacitors of the Vss plane. Between various steps in the assembly process, the capacitors can be discharged in a controlled manner through grounding. In aspects, grounding is not possible between various steps of the assembly process. In other aspects, grounding is too time consuming to be performed regularly during the assembly process. Accordingly, the capacitors of the Vss plane can continue to accumulate charge until the charge is released. This release of charge, which is sometimes referred to as an electrostatic discharge (ESD) event, can cause a high peak current to flow through the substrate to the semiconductor device. The peak current can create heat, thereby damaging circuitry (e.g., diodes) in the substrate or the semiconductor device.

### Example Substrate

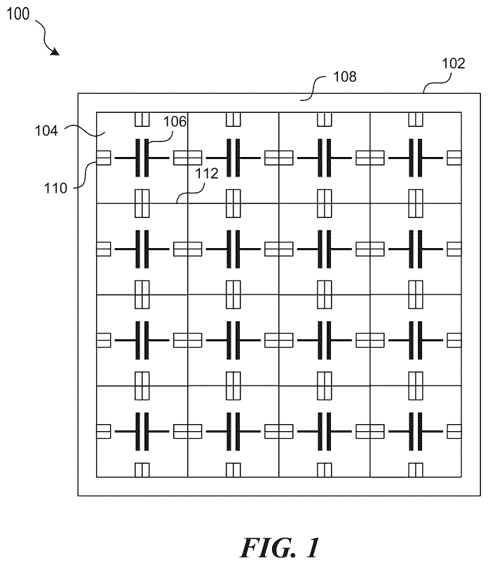

FIG. 1 illustrates a simplified schematic cross-sectional view of a substrate 100 in accordance with an embodiment of the present technology. The cross section is taken at a Vss plane 102 (e.g., ground plane) of the substrate 100. Thus, the cross-sectional view of the substrate 100 corresponds to a partial plan view of the Vss plane 102. The Vss plane 102 includes a plurality of Vss units 104, each of which is configured to provide a voltage source signal (e.g., a ground signal) to a respective semiconductor device coupled with the substrate 100. The Vss plane 102 can include any number of Vss units (e.g., 2, 4, 6, 8, 10, 20, 50, 100, or any other number) having the same size or various different sizes. The Vss units 104 include capacitors 106, which can act as filters for signaling between the substrate 100 and the respective semiconductor device.

In some substrates, the individual Vss units can be decoupled from one another. In this way, the Vss units have isolated capacitors. As semiconductor devices are assembled onto the substrate, charge can accumulate in the capacitors. To discharge the capacitors, the Vss plane can be grounded. Given that the Vss units are isolated, however, the Vss plane cannot be grounded through a single connection to a ground. Instead, ionizers can be used to discharge the capacitors without physically connecting a ground to the Vss plane. In some cases, this contactless grounding process is time intensive, which increases production time. In aspects, the contactless grounding process can discharge the capacitors more slowly than they are charged. Accordingly, ESD events can occur due to infrequent or ineffective grounding.

In contrast to substrates with isolated Vss units, the substrate 100 includes Vss units 104 that are coupled with one another through conductive traces. For example, the capacitors 106 of the Vss units 104 can couple through conductive traces. The Vss units 104 can further couple with a conductive rail 108 at least partially surrounding the Vss units 104 through conductive traces. The conductive rail 108 can include any conductive material through which electrical signals can travel. The conductive rail 108 can surround the periphery of the Vss plane 102. Thus, the Vss units 104 can communicatively couple with the conductive rail 108 through conductive traces. In aspects, each of the Vss units 104 can couple directly with the conductive rail 108 (e.g., through traces, lines, or other connective structures). Thus, in some embodiments, the Vss units 104 can connect exclusively through the conductive rail 108. In other aspects, only the Vss units 104 at the periphery of the Vss plane 102 are coupled directly with the conductive rail 108. The Vss units 104 at the periphery of the Vss plane 102 can further couple directly with the interior Vss units 104.

Given that the Vss units 104 are coupled with the conductive rail 108, the capacitors 106 can be discharged by electrically coupling a ground to the conductive rail 108. In some cases, clamps can be connected with the conductive rail 108 (e.g., through an additional conductive element electrically coupled with the conductive rail 108). In doing so, the Vss plane 102 can be grounded to discharge the capacitors 106. In other aspects, the clamps can be connected with a conductive element electrically coupled with the Vss units 104. In yet other aspects, the capacitors 106 can be discharged without connecting a ground to the Vss units 104 (e.g., contactless grounding using an ionizer).

Given that the Vss units 104 are connected with one another, the capacitors 106 can act as a single capacitor with a greater capacitance. For example, the capacitors 106 can be connected in parallel such that the capacitors 106 of the Vss plane 102 equate to a single capacitor with a capacitance equal to the sum of the individual capacitance of each of the capacitors 106. In some cases, some of the capacitors 106 can be implemented in parallel and others of the capacitors 106 can be implemented in series. In embodiments, the capacitors 106 can store a greater charge compared to the individual, isolated capacitors of a disconnected Vss plane 102. In this way, ESD events, where the charge stored in the capacitors is released, can create a higher peak current that flows through the circuitry at the substrate 100 or the semiconductor devices. The higher peak current can, in turn, generate greater amounts of heat, which can damage the circuitry.

The Vss units 104 further comprise current limiters 110 between adjacent Vss units or between a Vss unit and the conductive rail 108. The current limiters 110 can be implemented at conductive traces connecting the Vss units 104. In aspects, the current limiters 110 can separate the capacitors on adjacent Vss units or a capacitor on a Vss unit and the conductive rail 108. In some cases, two capacitors can be separated by multiple current limiters 110. For example, a first capacitor on a first Vss unit and a second capacitor on a second Vss unit can be separated by a first current limiter on the first Vss unit and a second current limiter on the second Vss unit. Alternatively, or additionally, the first Vss unit or the second Vss unit can include multiple current limiters that separate the first capacitor and the second capacitor.

As used herein, a current limiter can include a device capable of lowering the peak current through a system in response to an ESD event. For example, a current limiter can include a device that limits the rate of change of current through the device, such as an inductor. In other cases, a current limiter can include a device that reduces the total current through a system, such as a resistor. The inductance or resistance of the current limiters 110 can vary based on the specific embodiments. For example, the inductance or resistance of the current limiters 110 can be determined based on the capacitance of the capacitors 106 and an allowable peak current (e.g., a maximum peak current that does not cause damage to the substrate 100 or the coupled semiconductor devices).

The Vss units 104 can be separated by saw streets 112 at which the substrate 100 is sawed. Saw streets 112 can similarly separate the Vss units 104 and the conductive rail 108. Conductive traces coupling the Vss units 104 (e.g., with other Vss units 104 or with the conductive rail 108) can extend to the saw streets 112. Similarly, the current limiters 110 can extend to the saw streets 112. Accordingly, the conductive traces or the current limiters 110 can extend to an edge of the substrate once the individual Vss units 104 are separated from one another. In this way, the conductive traces or the current limiters 110 on different ones of the Vss units 104 can be disconnected from one another when the substrate 100 has been sawed.

Although illustrated with a single Vss plane 102, the substrate 100 can include additional power and ground planes. For example, the substrate 100 can include one or more additional Vss planes. In aspects, the substrate 100 is an organic substrate (e.g., a printed circuit board (PCB)). In other aspects, the substrate 100 can be a semiconductive substrate, such as a silicon interposer.

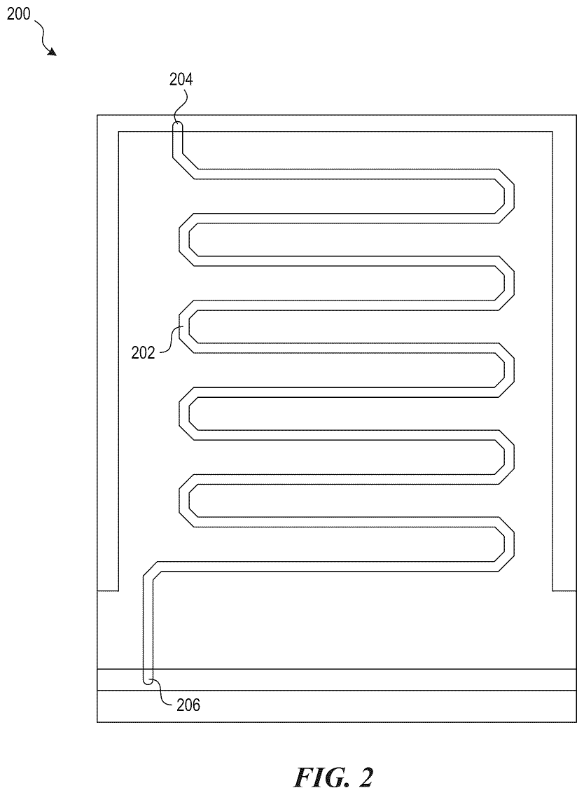

FIG. 2 illustrates a simplified schematic partial plan view of a current limiter 200 in accordance with an embodiment of the present technology. The current limiter 200 is implemented as a conductive trace 202 arranged in a serpentine pattern. Given that the current limiter 200 is a conductive trace 202 not requiring additional, expensive circuit components, the current limiter 200 can be implemented without large amounts of added cost. A first end 204 of the conductive trace 202 can connect (e.g., directly or indirectly through a conductive trace) to circuitry at a first Vss unit (e.g., a first capacitor), and a second end 206 can connect (e.g., directly or indirectly through a conductive trace) to the conductive rail or to circuitry at a second Vss unit (e.g., a second capacitor). In some cases, the conductive trace 202 can extend to a saw street of the first Vss unit.

As illustrated, the conductive trace 202 is arranged in a serpentine pattern in which the conductive trace 202 bends back on itself in the lateral direction. In this way, the conductive trace 202 can act as an inductor, which reduces the peak current resulting from an ESD event. The inductance can be defined by the size of the conductive trace 202 and the number of turns (e.g., coils). The conductive trace 202 can include any number of turns (e.g., at least 2, 3, 4, 5, 10, or any other number of turns). In aspects, the number of turns is defined as the number of times that the conductive trace 202 bends back on itself in the lateral direction. As illustrated, the conductive trace 202 includes 9 turns. The number of turns or the size of the conductive trace 202 can be varied based on the amount of charge capable of being stored in the capacitors and the allowable peak current (e.g., maximum current allowed before the circuitry is damaged).

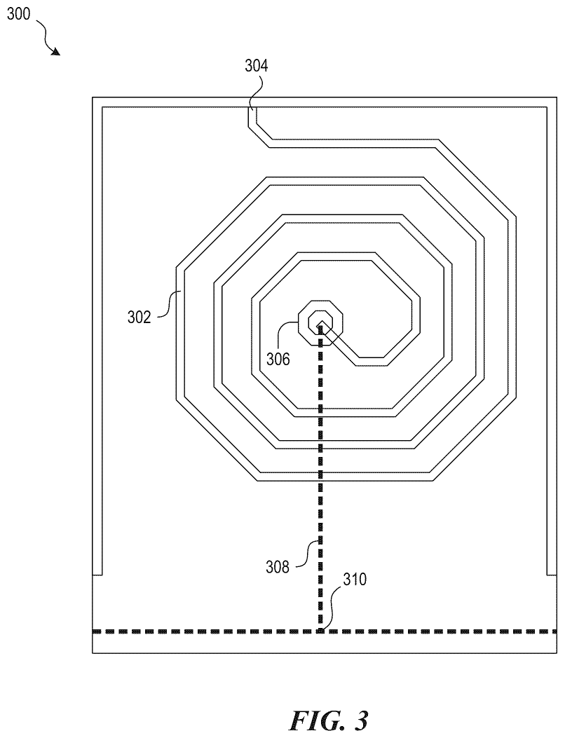

FIG. 3 illustrates a simplified schematic partial plan view of a current limiter 300 in accordance with an embodiment of the present technology. The current limiter 300 is implemented as a conductive trace 302 arranged in a spiral pattern. Given that the current limiter 300 is a conductive trace 302 not requiring additional, expensive circuit components, the current limiter 300 can be implemented without large amounts of added cost. The conductive trace 302 can be implemented on a first side of the Vss plane. A first end 304 of the conductive trace 302 can connect (e.g., directly or indirectly through a conductive trace) to circuitry at a first Vss unit (e.g., a first capacitor). The conductive trace 302 can continue in a spiral pattern to a center of the spiral at which a via 306 is implemented. The via 306 can extend from a first side of the Vss plane to a second side of the Vss plane opposite the first side.

A second conductive trace 308 can be implemented at the second side of the Vss plane extending to an edge of the first Vss unit. The second conductive trace 308 can have a second end 310 that can connect (e.g., directly or indirectly through a conductive trace) to the conductive rail or to circuitry at a second Vss unit (e.g., a second capacitor). In some cases, the second conductive trace 308 can extend to a saw street of the first Vss unit. In aspects, the first Vss unit or the second Vss unit can include an additional via that connects the second conductive trace 308 to a third conductive trace at the first side (not shown). In this way, the routing circuitry can be brought back to the first side.

As illustrated, the conductive trace 302 is arranged in a spiral pattern. In this way, the conductive trace 302 can act as an inductor, which reduces the peak current resulting from an ESD event. The inductance can be defined by the size of the conductive trace 302 and the number of winds (e.g., coils). The conductive trace 302 can include any number of winds (e.g., at least 2, 3, 4, 5, 10, or any other number of winds). In aspects, the number of winds is defined as the number of times that the conductive trace 302 forms a full 360-degree rotation. As illustrated, the conductive trace 302 includes more than 3 winds. The number of winds or the size of the conductive trace 302 can be varied based on the amount of charge capable of being stored in the capacitors and the allowable peak current (e.g., maximum current allowed before the circuitry is damaged).

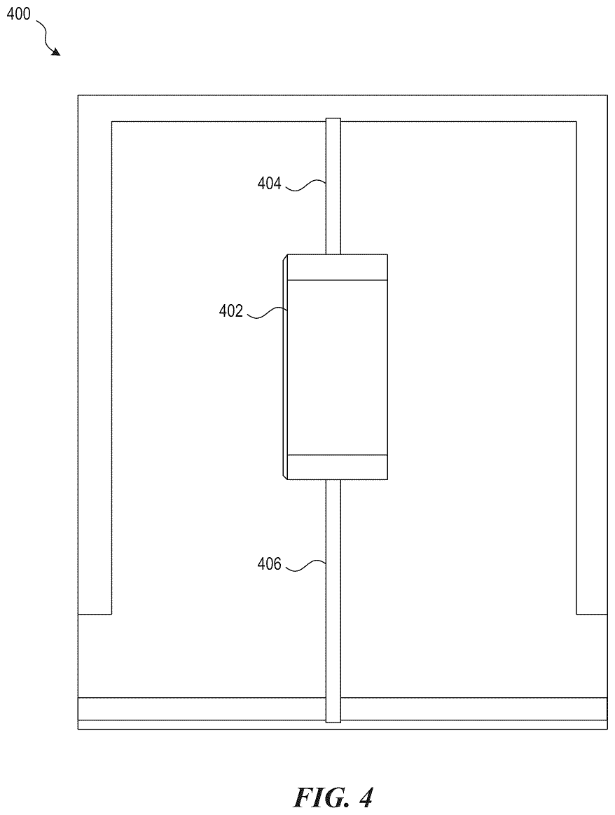

FIG. 4 illustrates a simplified schematic partial plan view of a current limiter 400 in accordance with an embodiment of the present technology. The current limiter 400 is implemented as a resistor 402 (e.g., a surface mount resistor) connected to a conductive trace. In some cases, the implementation of the current limiter 400 has a greater cost than the current limiter 200 or the current limiter 300 described with respect to FIGS. 2 and 3, respectively, given that the current limiter 400 utilizes an additional circuit component (e.g., resistor 402). A first conductive trace 404 can connect (e.g., directly or indirectly through a conductive trace) circuitry at a first Vss unit (e.g., a first capacitor) and the resistor 402, and a second conductive trace 406 can connect (e.g., directly or indirectly through a conductive trace) the resistor 402 and the conductive rail or circuitry at a second Vss unit (e.g., a second capacitor). In some cases, the second conductive trace 406 can extend to a saw street of the first Vss unit.

As illustrated, the current limiter 400 includes the resistor 402. In this way, the resistor 402 can limit the total current created by the release of charge from the capacitors during an ESD event. The resistance of the resistor 402 can be varied based on the amount of charge capable of being stored in the capacitors and the allowable peak current (e.g., maximum current allowed before the circuitry is damaged).

### Example Semiconductor Device Assembly

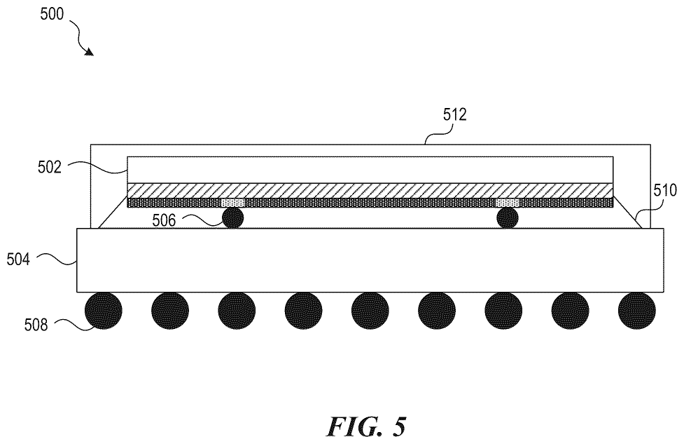

FIG. 5 illustrates a simplified schematic cross-sectional view of a semiconductor device assembly 500 in accordance with an embodiment of the present technology. A semiconductor device 502 is coupled with a substrate 504. The substrate 504 can be a singulated substrate in accordance with one or more embodiments described herein. For example, the semiconductor device 502 can be coupled with a panel-level or strip-level substrate (e.g., substrate 100 of FIG. 1) in alignment with a first Vss unit. The panel-level or strip-level substrate can then be sawed to singulate the substrate 504 and the semiconductor device 502. In some embodiments, the semiconductor device 502 can be replaced with a semiconductor device that includes a stack of semiconductor dies or a plurality of semiconductor dies.

The semiconductor device 502 can include contact pads at the front side that connect to a metallization layer (e.g., through traces, lines, vias, or other connection structures). The substrate 504 can similarly include contact pads at an upper surface. Interconnects 506 can be formed between the contact pads on the semiconductor device 502 and the contact pads on the substrate 504 to communicatively couple the semiconductor device 502 and the substrate 504. The substrate 504 can include various circuitry (e.g., traces, lines, vias, or other connection structures) between the contact pads at the upper surface and additional circuit elements. For example, the substrate 504 can include circuitry that connects power and ground planes (e.g., Vss plane 102 of FIG. 1) to the contact pads at the upper surface and thus enables the substrate 504 to provide voltage power and ground signals to the semiconductor device 502 through the interconnects 506. The substrate 504 can further include circuitry that extends to contact pads at a lower side of the substrate 504 at which connective structures 508 (e.g., solder balls) are disposed. In this way, external connectivity (e.g., power, ground, and input/output signaling) can be provided through the connective structures 508.

An underfill material 510 (e.g., capillary underfill) can be provided between the semiconductor device 502 and the substrate 504 to provide electrical insulation to the interconnects 506 and structurally support the semiconductor device assembly 500. The semiconductor device assembly 500 can further include an encapsulant material 512 (e.g., mold resin compound) that at least partially encapsulates the semiconductor device 502 and the substrate 504 to prevent electrical contact therewith or provide mechanical strength to the semiconductor device assembly 500.

In accordance with one aspect of the present disclosure, the semiconductor devices illustrated in the assemblies of FIGS. 1-5 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

### Example Systems

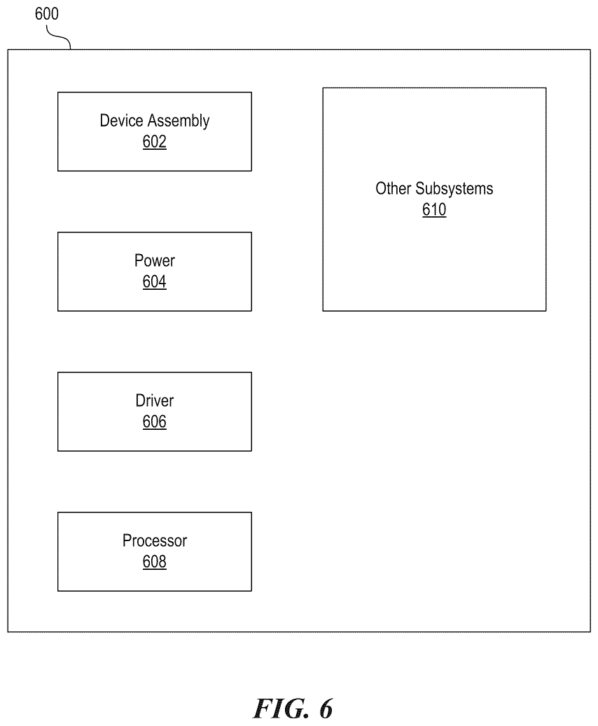

Any one of the semiconductor devices and semiconductor device assemblies described above with reference to FIGS. 1-5 can be incorporated into any of a myriad of larger and/or more complex systems, a representative example of which is system 600 shown schematically in FIG. 6. The system 600 can include a semiconductor device assembly 602 (e.g., a discrete semiconductor device), a power source 604, a driver 606, a processor 608, and/or other subsystems or components 610. The semiconductor device assembly 602 can include features generally similar to those of the semiconductor device assemblies described above with reference to FIGS. 1-5. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, vehicles, appliances, and other products. Components of the system 600 can be housed in a single unit or distributed over multiple, interconnected units (e.g., through a communications network). The components of the system 600 can also include remote devices and any of a wide variety of computer-readable media.

This disclosure now turns to methods for fabricating semiconductor device assemblies in accordance with one or more embodiments of the present technology. Although illustrated in a particular configuration, operations within any of the methods may be omitted, repeated, or reorganized. Moreover, any of the methods may include additional operations, for example, those detailed in one or more other methods described herein.

### Example Methods

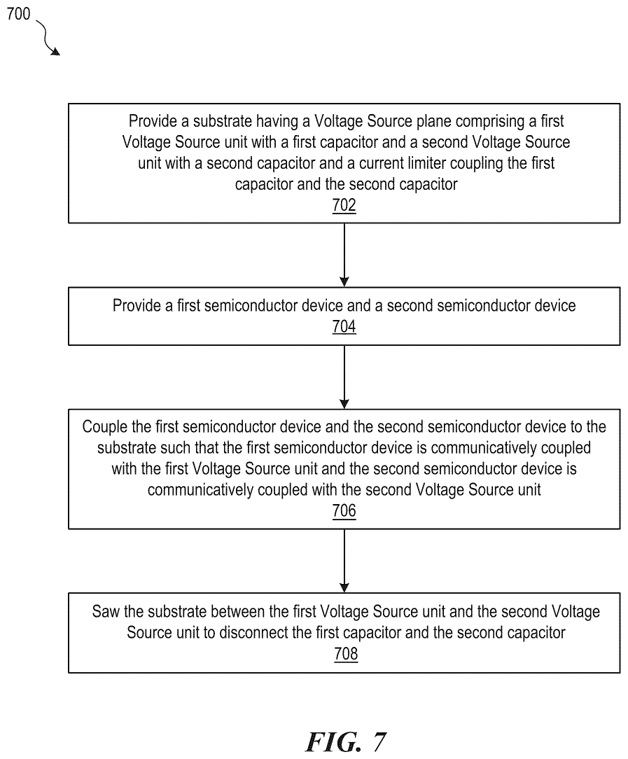

FIG. 7 illustrates a method 700 for fabricating a semiconductor device assembly. At 702, a substrate is provided. The substrate includes a Vss plane with a first Vss unit and a second Vss unit. The first Vss unit has a first capacitor, and the second Vss unit has a second capacitor and a current limiter coupling the first capacitor and the second capacitor. At 704, a first semiconductor device and a second semiconductor device are provided. At 706, the first semiconductor device and the second semiconductor device are coupled to the substrate such that the first semiconductor device is communicatively coupled with the first Vss unit and the second semiconductor device is communicatively coupled with the second Vss unit. At 708, the substrate is sawed between the first Vss unit and the second Vss unit to disconnect the first capacitor and the second capacitor. In doing so, a singulated semiconductor device assembly can be fabricated.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical mechanical planarization, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, can be formed on a semiconductor substrate or die, such as silicon, germanium, silicon-germanium alloy, gallium arsenide, gallium nitride, etc. In some cases, the substrate is a semiconductor wafer. In other cases, the substrate can be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, can be controlled through doping using various chemical species including, but not limited to, phosphorous, boron, or arsenic. Doping can be performed during the initial formation or growth of the substrate, by ion-implantation, or by any other doping means.

The functions described herein can be implemented in hardware, software executed by a processor, firmware, or any combination thereof. Other examples and implementations are within the scope of the disclosure and appended claims. Features implementing functions can also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications can be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A substrate comprising:
a Voltage Supply source (Vss) plane comprising a first Vss unit configured to provide a first Vss signal to a first semiconductor device and a second Vss unit configured to provide a second Vss signal to a second semiconductor device,
wherein the first Vss unit includes a first capacitor, and
wherein the second Vss unit includes a second capacitor coupled with the first capacitor and a current limiter coupling the first capacitor and the second capacitor.

2. The substrate of claim 1, wherein the second Vss unit includes an additional current limiter coupling the first capacitor and the second capacitor.

3. The substrate of claim 1, wherein the current limiter comprises a conductive trace arranged in a serpentine pattern.

4. The substrate of claim 3, wherein the serpentine pattern comprises at least five turns.

5. The substrate of claim 1, wherein the current limiter comprises:
a top side conductive trace arranged in a spiral pattern;
a bottom side conductive trace opposite the top side conductive trace; and
a via coupling the top side conductive trace and the bottom side conductive trace at a center of the spiral pattern.

6. The substrate of claim 5, wherein the spiral pattern comprises at least three winds.

7. The substrate of claim 1, wherein the current limiter comprises a surface mount resistor.

8. The substrate of claim 1, wherein:
the Vss plane further comprises a conductive rail at least partially surrounding the first Vss unit and the second Vss unit; and
the first Vss unit further comprises an additional current limiter coupling the first capacitor and the conductive rail.

9. The substrate of claim 1, wherein:
the Vss plane further comprises a third Vss unit having a third capacitor coupled with the second capacitor; and
the second Vss unit further comprises an additional current limiter coupling the third capacitor and the second capacitor.

10. The substrate of claim 1, wherein the substrate comprises a printed circuit board.

11. A semiconductor device assembly comprising:
a semiconductor device; and
a substrate coupled with the semiconductor device, the substrate comprising a Voltage Source (Vss) plane comprising:
a capacitor;
a conductive trace extending to an edge of the Vss plane; and
a current limiter coupling the capacitor with the conductive trace.

12. The semiconductor device assembly of claim 11, wherein the Vss plane further comprises:
an additional conductive trace extending to an additional edge of the Vss plane; and
an additional current limiter coupling the capacitor with the additional conductive trace.

13. The semiconductor device assembly of claim 11, wherein the current limiter comprises an additional conductive trace arranged in a serpentine pattern.

14. The semiconductor device assembly of claim 11, wherein the current limiter comprises:
a top side conductive trace arranged in a spiral pattern;
a bottom side conductive trace opposite the top side conductive trace; and
a via coupling the top side conductive trace and the bottom side conductive trace at a center of the spiral pattern.

15. The semiconductor device assembly of claim 11, wherein the current limiter comprises a surface mount resistor.

16. The semiconductor device assembly of claim 11, wherein the semiconductor device comprises a memory device.

17. The semiconductor device assembly of claim 11, wherein the substrate comprises a printed circuit board.

18. A method of fabricating a semiconductor device assembly comprising:
providing a substrate having a Voltage Source (Vss) plane comprising a first Vss unit with a first capacitor and a second Vss unit with a second capacitor and a current limiter coupling the first capacitor and the second capacitor;
providing a first semiconductor device and a second semiconductor device;
coupling the first semiconductor device and the second semiconductor device to the substrate such that the first semiconductor device is communicatively coupled with the first Vss unit and the second semiconductor device is communicatively coupled with the second Vss unit; and
sawing the substrate between the first Vss unit and the second Vss unit to disconnect the first capacitor and the second capacitor.

19. The method of claim 18, wherein:
the Vss plane further comprises a conductive rail at least partially surrounding the first Vss unit and the second Vss unit, the conductive rail communicatively coupled with the first capacitor and the second capacitor; and
the method further comprises clamping a conductive element communicatively coupled with the conductive rail to ground the Vss plane.

20. The method of claim 18, wherein:
the Vss plane further comprises a conductive rail at least partially surrounding the first Vss unit and the second Vss unit, the conductive rail communicatively coupled with the first capacitor and the second capacitor; and
the method further comprises sawing the substrate between the conductive rail and the first Vss unit and the second Vss unit to remove the conductive rail from the Vss plane.
